(19) United States
(12) Patent Application Publication
(10) Pub. No.: US 2025/0185383 A1
(43) Pub. Date: Jun. 5, 2025

(54) A UNITARY FILM FOR AN ELECTRODE ASSEMBLY OF A SOLAR CELL

(71) Applicant: REC Solar PTE. Ltd., Singapore (SG)

(72) Inventors: Toh Xin NGOH, Singapore (SG); Yiting LIANG, Singapore (SG)

(73) Assignee: REC Solar PTE. Ltd., Singapore (SG)

(21) Appl. No.: 18/725,716

(22) PCT Filed: Dec. 9, 2022
(86) PCT No.: PCT/EP2022/085158

§ 371 Date: Jun. 28, 2024

(30) Foreign Application Priority Data
Dec. 29, 2021 (GB) 2119068.1

(51) Int. Cl. H10F 19/90; H10F 71/00

(52) U.S. Cl. CPC H10F 19/906; H10F 71/00

(57) ABSTRACT

A unitary film for an electrode assembly of a solar cell, wherein the unitary film is arranged, when in use, on a surface of the solar cell and a plurality of electrically conductive elements of the electrode assembly are interposed between the unitary film and the surface of the solar cell; wherein the unitary film is formed of a polymeric material and is characterised by satisfying at least one of a first criterion and a second criterion: the first criterion requires that the polymeric material has at least two endothermic peaks in a temperature range between 40° C. and 200° C., and the second criterion requires that the unitary film has a peel strength of at least 5N per 10 mm width of the unitary film.

### CROSS-REFERENCE TO RELATED APPLICATIONS

This application is a U.S. National Phase Patent Application based on International Patent Application No. PCT/EP2022/085158, filed Dec. 9, 2022; which claims priority to GB Patent Application No. 2119068.1, filed Dec. 29, 2021. The above referenced applications are incorporated herein by reference in their entirety as if fully set forth herein.

### FIELD OF THE DISCLOSURE

The present disclosure relates to a unitary film for an electrode assembly of a solar cell.

### BACKGROUND

Solar modules for providing electrical energy from sunlight comprise an array of cells, each comprising a photovoltaic element, or substrate. The solar cells are typically connected so that electrical current is routed, via an electrical connector, from a front surface of one solar cell to a back surface of a second solar cell, or vice versa. Each of the electrical connectors comprises a plurality of electrically conductive elements (e.g. interconnecting wires) which form an electrical connection with electrodes arranged on the respective front and back surfaces of the solar cells.

A general aim for solar cell development is to attain high conversion efficiency balanced by a need for reduced production costs. Efforts to achieve this have focused on the electrical connections between the solar cells.

One approach has been to provide foil-wire electrodes which connect directly to finger electrodes arranged on the surface of each solar cell. An example of a foil-wire electrode is a SmartWire® solar cell connector. The foil-wire electrodes reduce electrical losses by minimising the impact of cell damage on the performance of the solar module. Furthermore, the use of foil-wire electrodes can also lead to a significant reduction in module production costs and optical losses arising from the light shading caused by configuring the solar cell's surfaces with conventional printed busbar electrodes.

The foil of the foil-wire electrode is a multi-layered transparent film. The foil comprises a support layer which provides a supporting structure for the foil, and an adhesive layer which attaches the foil to the wire connectors and to the solar cell surface. When the foil-wire electrode is arranged on the front surface of the solar cell, the foil may be configured with a front surface which faces away from the solar cell, and a back surface which faces towards the solar cell. The support layer is arranged at the front surface of the foil and the adhesive layer is arranged on the back surface of the foil, opposite the front surface.

The foil is constructed by laminating together the support layer and the adhesive layer. The adhesive layer is made of a polymeric material which can be heated to form a thermal bond, for example with the connecting wires.

During the construction of the foil-electrode, the foil is overlaid onto the connecting wires so that the adhesive layer is brought into contact with the connecting wires. Heat and pressure are applied to the foil to thermally bond the foil to the connecting wires.

Two solar cells are electrically connected together by a foil-electrode to form a solar cell assembly. A first end of the foil-wire electrode is overlaid onto the surface of a first solar cell such that the connecting wires are interposed between the foil and the solar cell surface. Heat and pressure are applied to the foil to cause the adhesive layer to thermally bond the foil to the solar cell surface. A second end of the foil-wire is connected to the surface of a second solar cell in the same manner. Accordingly, the foil-wire electrode provides a means of forming an electrical connection between the solar cells of a solar cell assembly.

Despite these developments, there remains a need to improve the electrical connections between the solar cells of a solar assembly.

### SUMMARY

According to a first aspect, there is provided a unitary film for an electrode assembly of a solar cell (e.g., a foil-wire electrode assembly). The unitary film is arranged, when in use, on a surface of the solar cell and a plurality of electrically conductive elements of the electrode assembly are interposed between the unitary film and the surface of the solar cell; wherein the unitary film is formed of a polymeric material and is characterised by satisfying at least one of a first criterion and a second criterion.

The first criterion requires that the polymeric material has at least two endothermic peaks (e.g., endothermic melting peaks) in a temperature range between 40° C. and 200° C. measured by differential scanning calorimetry using the following method:
heating the unitary film, sequentially, in a first thermal cycle and a second thermal cycle according to Standard Test Method ASTM D3418 to produce a first heating trace and a second heating trace, respectively; and
identifying and determining a first endothermic peak and a second endothermic peak, in each of the first and second heating traces, in the temperature range between 40° C. and 200° C.

The second criterion requires that the unitary film has a peel strength of at least 5N per 10 mm width of the unitary film. The peel strength is determined (e.g., measured) by 180-degree peel test according to the following method:
thermally bonding the unitary film to a surface (e.g., a receiving surface) of a substrate;
peeling the unitary film from the substrate according to Standard Test Method ASTM D903 to provide a peel-force trace; and
determining, from the peel-force trace, that the unitary film has a peel strength of at least 5N per 10 mm width of the unitary film.

It will be appreciated that the unitary film may define a film which forms a single or uniform entity (e.g., it is not comprised of a plurality of layers formed of different materials).

It will be appreciated that the first and second criteria each comprise methods of identifying and determining physical properties of the material of the uniform film. Also, it will be appreciated that these methods do not necessarily limit the claimed unitary film. Rather, they merely provide a way to determine whether the unitary film has one or more of the characteristic physical properties according to the present disclosure.

The first criterion refers to Standard Test Method ASTM D3418, which is a standard test method for transition temperatures and enthalpies of fusion and crystallisation of polymers by differential scanning calorimetry. A technical advantage of the unitary film, as characterised by the first criterion, is that it exhibits an advantageous phase transition temperature range, which is useful for preventing instability in the unitary film during use. For example, in situations where the unitary film is thermally bonded to the conductive elements (e.g., in order to form an electrode assembly), or when the unitary film is thermally bonded to a surface of a solar cell (e.g., in order to form a solar cell assembly). The first criterion refers to a method of identifying and determining the at least one temperature of an endothermic peak of the polymeric material of the unitary film. This testing method can be used to identify and determine whether a candidate polymeric material exhibits an endothermic phase transition in the required temperature range, such that it would fall within the scope of the present disclosure.

The second criterion refers to Standard Test Method ASTM D903, which is a standard test method for peel (or stripping) strength of adhesive bonds. The peel strength represents the average load per unit width at a bond line between the film and the substrate, which is required to separate the unitary film, progressively, from the substrate at an angle of approximately 180° and at a separation rate of 152 mm/min. The peel strength may be expressed as a force per unit width (e.g., Newtons (or kilograms) per millimetre of width of the unitary film). The bond line extends parallel to the width of the unitary film, and defines a line of contact between the film and substrate's surface.

A technical advantage of the unitary film, as characterised by the second criterion, is that it exhibits an advantageous range of peel strengths, which are associated with improved adhesive properties of the unitary film. For example, the testing method of the second criterion can be used to identify and determine whether a candidate polymeric film exhibits a peel strength in the required range (e.g., at least 5N per 10 mm width of the unitary film), such that it would fall within the scope of the present disclosure.

The peel strength represents a standard measure of the adhesive properties of a film, as determined by Standard Test Method ASTM D903. It will be appreciated that the width direction of the unitary film is substantially perpendicular to the direction in which the peel-force is applied to the unitary film during the 180-degree peel test. The adhesive properties may also be defined by the peel strength of the unitary film, which is expressed in units of kg per mm width of the unitary film.

A unitary film satisfying the requirements of the first and/or second criteria provides increased adhesion, when in use, between the plurality of conductive elements and the unitary film and/or between the solar cell and the unitary film. Furthermore, the unitary nature of the film means that it exhibits substantially uniform physical and thermal properties, (e.g., in comparison to a multi-layer film which includes separate backing and adhesive layers which may have different properties). For example, the unitary film is less prone to delamination. Accordingly, the unitary film is more stable and simpler to handle during the fabrication of the solar cell assembly, which can lead to improvements in the efficiency of the fabrication process.

Optional features will now be set out. These are applicable singly or in any combination with any aspect.

It will be appreciated that the unitary film may be defined by at least one, or both, of the first and second criteria (e.g., the first criterion and the second criterion).

As described above, the DSC testing method of the first criterion comprises identifying at least two endothermic peaks in a trace (e.g., a heating or cooling trace) produced by differential scanning calorimetry. The trace may be generated by a differential scanning calorimeter configured to determine the temperature and heat flow associated with a thermal transition of a material under investigation. In general, thermal transitions may be characterised by the absorption or release of energy by the specimen resulting in a corresponding endothermic or exothermic peak or baseline shift in the trace. For example, the areas under the crystallisation exotherm, or fusion endotherm, of the test materials may be compared against the corresponding areas of traces obtained by testing a well characterised standard.

To obtain a trace, the material (e.g. a sample of the polymeric material) may be placed in a test cell of the calorimeter, which is coupled to an empty reference cell. The calorimeter monitors the heat flow between the two cells as they are heated up. The heat flow between the cells is normally constant when the material isn't undergoing a phase transition. As the temperature rises (e.g., in the case of a heating trace), the material may, at a certain temperature, undergo a transition (e.g. an endothermic transition) which requires heat to be transferred from the reference cell to the test cell.

The calorimeter may be configured to output a trace corresponding to the flow of heat being directed either towards, or away from, the test cell (i.e. a test trace). A separate trace is typically also produced corresponding to the reference cell (i.e. a reference trace), which is typically a flat line. The difference between the test trace and the reference trace is representative of the change in heat flow to the test cell with changing temperature. Such changes may correspond to a transition in the material under investigation.

It will be understood that the calorimetric data can be evaluated to determine characteristic properties of the material under investigation. The data may be presented as traces on a graph of heat flow (W/g) plotted against temperature (° C.) and/or time(s). The heat flow values represent the power per unit mass that is directed between the cells of the calorimeter. The temperature values correspond to the measured temperature of the cell. The time values are representative of the rate at which the temperature of the cells increase during the investigation.

The peak may appear on the resulting graphs as a region of the test trace that deviates from the substantially linear reference trace. In the case of an endothermic transition, the resulting peak may appear in the test trace as a negative peak, or trough.

As described above, the differential scanning calorimetry testing method of the first criterion involves identifying and determining the presence of a first endothermic peak and a second endothermic peak in each of the first and second heating traces, and determining that the first and second endothermic peaks, in each of the first and second heating traces, are at a temperature between 40° C. and 200° C. According to an exemplary arrangement, the first and/or second heating traces may comprise only two endothermic peaks within the defined temperature range (e.g., between 40° C. and 200° C.).

In situations where more than one peak is identified in a heating trace (e.g., a first and a second endothermic peak), the first peak may be defined as the peak which has the lowest temperature (e.g., a first peak temperature) and the second peak may be defined as the peak which has a peak temperature (e.g., a second peak temperature) that is greater (e.g., higher) than the temperature of the first peak. It will be appreciated that, in certain exemplary arrangements, there may be one or more peaks positioned between the first and second peaks of the trace. If a trace has three peaks, then the third peak may be defined as the peak which exhibits a peak temperature (e.g., a third peak temperature) that is greater than the first and second peak temperatures.

The first heating trace may be measured during the first thermal cycle performed by the differential scanning calorimeter, whilst the second heating trace may be measured during the second thermal cycle. The first and second thermal cycles may be performed sequentially according to Standard Test Method ASTM D3418.

The temperature of the endothermic peak (e.g., the first or second endothermic peaks) may define a peak temperature (Tp) of the endothermic peak (e.g., first or second peak temperatures, respectively). The peak temperature may represent the characteristic temperature of the endothermic transition (e.g. endothermic melting).

The peak temperature may be calculated from a trace (e.g., the first or second heating traces) plotted on a graph of heat flow vs. temperature. The peak temperature may be calculated by identifying a minimum value of the peak, i.e. a value which is less than its nearest neighbouring values. In the case of such polymeric materials, the minimum temperature may be indicative of the average melting temperature of crystallites in the material. For a second order phase transition (e.g., a glass transition), the minimum temperature may be the characteristic temperature of the phase transition.

The first peak temperature may define a temperature at the lowest point of the test trace (e.g., the first or second heating trace) in the region corresponding to the first endothermic peak. Accordingly, the first peak temperature may define a local minimum heat flow value (e.g. measured in power per unit mass, W/g) of the trace.

At least one, or each, of the first and second endothermic peaks of the first heating trace may be between 80° C. and 160° C. Alternatively, or additionally, at least one, or each, of the first and second endothermic peaks of the second heating trace may be between 80° C. and 160° C. According to an exemplary arrangement, the first and/or second heating traces may comprise only two endothermic peaks (e.g., the first and second peaks) within the defined temperature range (e.g., between 80° C. and 160° C.).

The first endothermic peak in at least one, or each, of the first and second heating traces may be between 40° C. and 130° C.

The first endothermic peak in the second heating trace may be between 80° C. and 130° C.

The second endothermic peak in at least one, or each, of the first and second heating traces may be between 100° C. and 160° C.

The second endothermic peak in at least one, or each, of the first and second heating traces may be between 100° C. and 145° C.

According to an exemplary arrangement of the unitary film, the second endothermic peak in the first heating trace (e.g., only the first heating trace) may be between 100° C. and 135° C. According to a further exemplary arrangement, the second endothermic peak in the first and second heating traces may be at a temperature between 100° C. and 145° C., optionally between 100° C. and 135° C.

The differential scanning calorimetry method of the first criterion may comprise identifying a third endothermic peak in at least one, or each, of the first and second heating traces. The method may further comprise determining that the third endothermic peak (e.g., in at least one, or each, of the first and second heating traces) is at a temperature between 130° C. and 200° C. The third endothermic peak in at least one, or each, of the first and second heating traces may be between 130° C. and 160° C. According to an exemplary arrangement, the first and/or second heating traces may comprise up to three endothermic peaks (e.g., the first, second and third peaks) within the defined temperature range (e.g., between 80° C. and 160° C.).

Accordingly, the unitary film may have a third endothermic peak in a temperature range between 130° C. and 200° C. in the first and second heating traces.

The differential scanning calorimetry method of the first criterion may comprise measuring the cooling of the polymer material during the first thermal cycle (e.g., a cooling stage of the first thermal cycle) according to Standard Test Method ASTM D3418 to produce a cooling trace.

As with the heating trace, the cooling trace may consist of a heat flow (W/g) plotted against temperature (° C.) and/or time(s). However, in this case the trace is recorded when the sample material is being cooled.

The unitary film may comprise an exothermic peak (e.g., an exothermic crystallisation peak) at a temperature in the range between 0° C. and 200° C. The exothermic peak may be measured by the differential scanning calorimetry method (e.g., according to Standard Test Method ASTM D3418). The by the differential scanning calorimetry method may further comprises measuring the cooling of the polymer material during the first thermal cycle to produce a cooling trace; and identifying and determining an exothermic peak at a temperature between 0° C. and 200° C. The exothermic peak may be between 40° C. and 130° C.

The thermal cycle (e.g., the first and/or second thermal cycles) may comprise a heating stage in which the test and reference materials are heated over time. During the heating stage, the calorimeter may be controlled to continuously monitor (e.g., with a temperature sensor) the differences in thermal input between a reference material and a test material, to produce a heating trace. For example, the heating stage of the first thermal cycle may produce a first heating trace and the heating stage of the second thermal cycle may produce a second heating trace.

The thermal cycle (e.g., the first and/or second thermal cycles) may also comprise a cooling stage, which may follow the heating stage, and during which the test and reference materials may be allowed to cool over time. During the cooling stage, the temperatures of the reference and test materials may be continuously monitored to produce a cooling trace. For example, the cooling stage of the first thermal cycle may follow the heating stage of the first thermal cycle, and may produce a cooling trace. The cooling trace shows the release of thermal energy from the test material, which was absorbed during the heating stage.

At least one, or each, of the thermal cycles (e.g., the first and second thermal cycles) may comprise heating and/or cooling the test material at a controlled rate (e.g., a controlled heating and/or cooling rate). For example, the heating rate of the thermal cycle may be 10° C./min. The rate of change of the sample temperature may be maintained within an error margin of ±0.1° C./min. The cooling rate may be substantially the same as the heating rate (e.g., 10° C./min). At the end of the heating stage (e.g., mid-way through the thermal cycle) the sample may be held at a first holding temperature (e.g., around 300° C.) for around 5 minutes. Similarly, at the end of the cooling stage (e.g., at the end of the thermal cycle) the sample may be held at a second holding temperature (e.g., around −50° C.) for around 5 minutes.

The differential scanning calorimetry method may be carried out in an inert atmosphere (e.g., under a purge, or flow, of inert gas). The testing environment (e.g., including the testing and/or reference samples) may be purged with inert gas at a purge flow rate of 50 mL/min. The inert gas may be nitrogen.

As described above, the testing method of the second criterion comprises peeling the unitary film from the substrate according to Standard Test Method ASTM D903 to provide a peel-force trace. The method may also comprise determining from the peel-force trace that the unitary film has a peel strength of at least 5N per 10 mm width of the film.

It will be understood that peel test may be used to determine (e.g., measure) the adhesion between the unitary film and the substrate which are thermally bonded together. A peel test apparatus may be used to perform the peel test. The peel test apparatus may comprise a motorised tensiometer configured to apply a tensile force between the unitary film and the substrate. The apparats may include a tensile force measuring sensor (e.g., a loadcell) to determine the tensile load that is applied during testing. The peel test apparatus may include a set of grips, or grippers, which are configured to hold the unitary film and the substrate. The peel test apparatus may comprise a controller which is configured to operate the motorised tensiometer to carry out the testing method. In particular, the controller may be capable of controlling the force that is applied to the grippers by the tensiometer, which thereby determines the force (e.g., the ‘peel force’) that is applied to the unitary film.

In an exemplary arrangement, the peel test method may comprise determining, from the peel-force trace, that the peel strength of the unitary film is at least 10 N. Alternatively, the peel strength may be at least 15 N per 10 mm width of the unitary film. The peel strength of the unitary film may be up to 30 N per 10 mm width of the unitary film.

As described above, the second criterion may also be characterised by thermally bonding the unitary film to a substrate. This method step may comprise heating the unitary film to at least 40° C. The peel test may comprise allowing the unitary film to cool (e.g., to room temperature (e.g., around 20° C.)) for a pre-determined period (e.g., at least 30 minutes) before carrying out the peel-force analysis of the unitary film (e.g., before peeling the film from the substrate).

The peel test method of the second criterion may comprise arranging the unitary film so that it lies substantially flat on a receiving surface of the substrate. This may be done before the film is thermally bonded (e.g., laminated) to the substrate. Only a portion of the unitary film may be thermally bonded to the substrate. Accordingly, the film may be configured with a free end (e.g., a non-bonded end) which can be readily coupled to a gripper of the peel-test apparatus.

The unitary film may be arranged in a longitudinal strip. A plurality of longitudinal strips may be arranged (e.g., in parallel to each other) on the surface of the substrate. The longitudinal strip may comprise a width of around 10 mm. The length of the longitudinal strip may comprise a length of at least 100 mm. The longitudinal strip may be arranged on the substrate such that the width of the strip is substantially perpendicular to the direction in which the peel-force is applied.

The peel test may be applied over a distance (e.g., strain) of around 100 mm. The unitary film may be peeled from the substrate at a peeling speed of around 100 mm/min. The peel-force is continuously monitored. For example, the peel-force may be measured at 10 μm intervals until the maximum peeling distance is reached (e.g., 100 mm).

The peel strength may be determined by taking an average of the data recorded in the peel-force trace. The average peel-force may be determined by averaging the data that is recorded after a minimum peeling distance, or strain, (e.g., 20 mm). The data taken before the peeling distance may be discounted, to prevent distortions of the measurement caused by noise in the data which is present at the beginning of each test run.

The substrate may be formed of a rigid material, such as glass or metal (e.g., a metal alloy). The substrate may comprise a solar cell (e.g., a crystalline silicon solar cell).

The unitary film may be configured, in use, to be mechanically attached (e.g., thermally bonded) to a plurality of electrically conductive elements (e.g., conductive wires or conductive wire portions). The unitary film may be configured with a surface (e.g., an element receiving surface) for receiving the elements. Once the elements are arranged on the unitary film's surface, they may be mechanically fixed in position to form an electrode assembly.

The unitary film may be configured to be insulating and/or optically transparent. The polymeric material may be formed from a polymer resin which comprises at least one of a polyolefin elastomer (POE), polyvinylbutyral (PVB) hydrocarbon ionomer, thermoplastic organo-silicon, silicon rubber, polyurethane, thermoplastic silicone elastomer (TPSE) and ethylene-vinyl acetate (EVA).

The unitary film may be formed of a polymeric material having at least one of the following characteristics: high ductility, low electrical conductivity, high optical transparency, thermal stability, and resistance to shrinkage.

The unitary film may be configured with a haze parameter of less than 35%, optionally up to 18%, further optionally up to 25%. It will be understood that the haze parameter of a polymeric material may be defined as a measure of the proportion of incident light which is scattered by more than 2.5°. It will be understood that the haze parameter of a material can be measured using a hazemeter or a spectrophotometer.

The unitary film may be configured to transmit at least 70% of incident light having a wavelength of between 280 nm and 1100 nm. Alternatively, the film may be configured to transmit at least 85% of incident light having a wavelength of between 280 nm and 1100 nm. The unitary film may have a thickness of at least 25 μm. The thickness of the unitary film may be between 55 μm and 180 μm.

In a second aspect of the disclosure, there is provided an electrode assembly which comprises a solar cell, and an electrode assembly of any one of the preceding statements. The plurality of electrically conductive elements are arranged on a surface (e.g., a conductive element receiving surface) of the unitary film, such that the electrode assembly can be arranged on a surface of the solar cell, so that the plurality of conductive elements are interposed between the unitary film and the solar cell's surface. Due to the advantageous physical properties of the unitary film (e.g., as characterised by the first and/or second criteria), the electrode assembly is advantageously configured to form a robust and conductive electrical connection with the surface of the solar cell.

According to a third aspect of the disclosure, there is provided a solar cell assembly. comprising at least one solar cell and an electrode assembly of any one of the preceding statements. The plurality of electrically conductive elements may be interposed between the unitary film and a surface (e.g., an electrode assembly receiving surface) of the solar cell. The solar cell assembly may be manufactured according to the method of any one of the preceding statements. As described above, the electrode assembly comprises a unitary film and a plurality of electrically conductive elements.

According to an exemplary arrangement, the solar cell assembly may comprise a first solar cell and a second solar cell. The at least one or each of the solar cells may comprise a layered structure which includes a photovoltaic element that can absorb light and generate charge carriers, as would be understood by the skilled person. The electrode assembly may be configured to form an electrical connection with a conductive surface (or a conductive portion of a surface) of the solar cell, to extract photogenerated charge carriers from the solar cell.

At least one, or each, of the solar cells may comprise a front surface and a back surface. The front surface may define the surface of the solar cell upon which light is incident when the solar cell assembly is in use (e.g. the frontmost surface of the solar cell). The back surface may define the surface of the solar cell which is opposite the front surface (e.g. the backmost surface of the solar cell). The back surface of the solar cell may not be directly exposed to incident light during use. The solar cell assembly may be configured so that light transmitted (e.g., not absorbed) from front to back through the solar cell is then reflected back towards the solar cell's back surface, which provides a further opportunity for the light to absorbed.

At least one, or each, of the electrically conductive elements may comprise an elongate form, such as a wire or wire portion. The conductive element may comprise a single integrally formed element (e.g. a wire). Configuring the conductive elements in this way removes the need to provide separate connections (such as copper ribbons) between neighbouring solar cells, which thereby reduces the number and complexity of manufacturing steps required to fabricate the solar cell assembly.

At least one, or each, of the electrically conductive elements may comprise a width, an axial length, and a depth. Each of the conductive elements may be configured such that its axial length is substantially greater than its width and/or depth. The width and axial length of the conductive elements may be measured in perpendicular directions aligned with a plane of the surface of the solar cell upon which the conductive elements are arranged (e.g. the front or back surface of the solar cell). The depth may be measured in a direction which is perpendicular to the same plane of the solar cell.

At least one, or each, of the electrically conductive elements may be formed of an electrically conductive material, such as a metal or metal alloy material, which may include at least one of Ag, Al, Au and Cu.

At least one, or each, of the electrically conductive elements may be connectable to the solar cell surface by applying heat and pressure to a coating on the conductive element to form a mechanical and electrical connection with the surface of the solar cell. The coating (e.g. a solderable coating) may comprise an electrically conductive material having a melting point which is lower than that of the conductive element. The coating may comprise a metal alloy formed of at least two or more components.

As described above, the solar cell assembly may comprise a first solar cell and a second solar cell, wherein the plurality of electrically conductive elements are configured to electrically couple a front surface of the first solar cell with a back surface of the second solar cell. During the construction of the solar cell assembly, the electrode assembly may be connected (e.g. laminated) onto the respective front and back surfaces of the first and second solar cells. At least one of the first and second solar cells may be inverted such that their front surfaces are arranged to face in a substantially downward direction (e.g. substantially vertically down) and their back surfaces are arranged to face in a substantially upward direction (e.g. substantially vertically up).

When the electrode assembly is in use, a first surface of the at least one electrically conductive element may be arranged to contact the front surface of the first solar cell, and to face away from the back surface of the second solar. Accordingly, a second surface of the at least one conductive element may be arranged to contact the back surface of the second solar cell, and to face away from the front surface of the first solar cell.

The first and second surfaces may define upper and lower surfaces of the conductive element(s), respectively. At least one, or each, of the first and second surfaces may extend in a longitudinal direction along the length of the conductive element. The first surface may be arranged on a directly opposite side of the conductive element to the second surface.

A first portion of the electrode assembly which contacts the front surface of the first solar cell may define a front connecting portion, or front connector, of the electrode assembly. A second portion of the electrode assembly, which contacts the back surface of the second solar cell, may define a back-connecting portion, or back connector of the electrode assembly.

A first portion of each of the plurality of electrically conductive elements may define the front connector of the electrode assembly. A second portion of each of the plurality of conductive elements may define the back connector of the electrode assembly. Accordingly, at least one, or each, of the plurality of conductive elements may extend from the front connector to the back connector of the electrode assembly.

The electrically conductive element(s) may be configured to bend along an axial direction of the conductive element(s) so as to allow the electrode assembly to be coupled between the respective front and back surfaces of the first and second solar cells (i.e. to allow the conductive element(s) to provide an electrical connection between the front and back connectors).

The first surface of the conductive element(s) of the back connector may be arranged to define a back surface (i.e. a backmost surface) of the electrode assembly. The second surface of the electrically conductive element(s) of the front connector may be arranged to define a front surface (i.e. a frontmost surface) of the electrode assembly.

As described above, the electrically conductive elements of the front and back connectors may define, respectively, a first and second portion of the plurality of conductive elements. The first portion of the plurality of conductive elements may be arranged in or on a first unitary film (e.g. an insulating and/or optically transparent film). The second portion of the plurality of conductive elements may be arranged in or on a second unitary film (e.g. an insulating and/or optically transparent unitary film). Accordingly, the first surface may be exposed from the first unitary film to form an electrical contact with the front surface of the first solar cell, and/or the second surface may be exposed from the second unitary film to form an electrical contact with the back surface of the second solar cell.

A third portion of the plurality of conductive elements may be arranged between the first and second portions of the plurality of conductive elements. The third portion may be configured to be arranged between the first and second solar cells when the electrode assembly is connected therebetween. The third portion may be configured such that the conductive elements in this portion are not arranged in a unitary film (i.e. in contrast to the first and second portions).

At least one, or each, of the conductive elements may be disposed on a surface of the respective first and second unitary films. Alternatively, or in addition, at least one of the conductive elements may be arranged at least partially within the unitary film. In this way, the at least one conductive element may be embedded within the unitary film such that a surface of the conductive element protrudes from the surface of the unitary film.

When in use, the first unitary film of the front connector may define a front unitary film of the electrode assembly. Similarly, the second unitary film of the back connector may define a back unitary film of the electrode assembly. The front unitary film may be configured such that at least a portion of the first surface of the front connector's conductive elements is exposed. The back unitary film may be configured such that at least a portion of the second surface of the back connector's conductive elements is exposed.

The unitary film of the front connector may have a back surface (i.e. facing towards the solar cell), and a front surface (i.e. facing away from the solar cell) opposite the back surface. At least one conductive element of the first portion of the plurality of conductive elements may be disposed on the back surface of the front unitary film.

The unitary film of the back connector may have a front surface (i.e. facing towards the solar cell), and a back surface (i.e. facing away from the solar cell) opposite the front surface. At least one conductive element of the second portion of the plurality of conductive elements may be disposed on the front surface of the back unitary film.

Each of the first and second solar cells may comprise a length, a width, and a depth. The length of the solar cell may be less than its width, and the depth may be less than both the width and the length. The longitudinal and transverse directions across the front and back surfaces of the solar cell may be parallel with the length and width directions of the solar cell, respectively. Hence, the plurality of conductive elements may be configured to extend across the length of the solar cell, and to be spaced along its width.

Each of the conductive elements may be configured to extend lengthwise relative to the surface of the solar cell upon which it is overlaid, in a longitudinal direction. The conductive elements may be spaced apart in a transverse direction relative to the solar cell surface to define longitudinal-extending spaces between the conductive elements. The conductive elements may be parallel or substantially parallel to one another. The conductive elements may be equally or substantially equally spaced in the transverse direction. Accordingly, the plurality of conductive elements may form an array of parallel, transversely spaced (e.g. equally spaced) conductive elements.

As described above, the conductive element(s) may be configured to form an electrical contact with an electrically conductive surface (e.g. an electrically conductive portion of a surface) of the solar cell. The conductive surface(s) may comprise one or more finger electrodes that are arranged on (e.g., printed on) the front and back surfaces of the layered structure. The one or more finger electrodes may be configured to conduct away charge carriers that are generated by the layered structure.

Each of the solar cells' conductive surface(s) may comprise a plurality of finger electrodes which extend across the respective solar cell surfaces, as would be understood by the skilled person. The finger electrodes may be formed using a printed material, which enables them to be conveniently deposited onto the surfaces of the solar cells.

The solar cell of the solar cell assembly may comprise a plurality of layers, or elements, including a photovoltaic element, wherein at least one of the plurality of layers is formed of a semiconductor material. The photovoltaic element (or layer) may be formed of a crystalline silicon wafer.

It will be appreciated that the solar cell may be configured to define any type of solar cell structure. For example, the solar cell may define a heterojunction type solar cell. Alternatively, the solar cell may define a tandem junction solar cell.

The surface(s) of the solar cell may be textured to form a textured surface corresponding to an uneven surface or having uneven characteristics, as would be understood by the skilled person. The textured surface may define an anti-reflection layer, or coating, arranged at the front and/or back surfaces of the solar cell.

The solar cell may comprise a transparent conductive oxide coating arranged at the front and/or back surfaces of the solar cell. The transparent conductive oxide coating may be configured to increase lateral carrier transport to the finger electrodes arranged on the respective surfaces of the solar cell.

According to an exemplary arrangement, the conductive elements may at least in part form the electrode assembly which is applied to the first and second solar cells to define the solar cell assembly. Furthermore, one or more solar cell assemblies according to the present invention may be electrically coupled together and arranged in a housing to define a solar module.

According to an exemplary arrangement, a second electrode assembly may be provided to couple the front surface of the second solar cell to the back surface of a third solar cell. The conductive elements in the second electrode assembly may be as described above for the first electrode assembly. In this situation, the second and third solar cells may be combined with the second electrode assembly to define a second solar cell assembly. The conductive elements of the back connector of the first electrode assembly may be aligned with the conductive elements of the front connector of the second electrode assembly, with the second solar cell interposed therebetween.

The solar module may comprise a frame in which to house the plurality of solar cell assemblies. The frame may comprise a front plate and a back plate which are arranged, respectively, on the front and back sides of the plurality of solar cell assemblies. At least one or each of the front and back plates may be formed of glass (e.g. a glass sheet). The solar module may comprise an encapsulant which may be configured to provide adhesion between the front and back plates and the plurality of solar cell assemblies. In this way, the encapsulant may be arranged between the glass sheet of the solar module, and an insulating optically transparent unitary film of one of the pluralities of solar cell assemblies. Also, the encapsulant may be arranged between the back sheet of the solar module, and an insulating optically transparent unitary film of one of the pluralities of solar cell assemblies. The encapsulant may be configured to prevent the ingress of moisture into the solar module. Accordingly, the encapsulant may be formed of ethylene vinyl acetate (EVA), or any other suitably moisture resistant material.

In a fourth aspect, the electrode assembly of the second aspect may be formed according to a manufacturing method of the present disclosure. The method comprises thermally bonding the unitary film to the plurality of electrically conductive elements. The unitary film is formed of a polymeric material according to any one of the preceding statements (e.g., which is characterised by a first criterion and/or a second criterion, as described above).

According to a fifth aspect of the present disclosure, there is a provided a method of manufacturing a solar cell assembly according to the third aspect. The method comprises interposing the plurality of electrically conductive elements between the unitary film and a surface of the solar cell. The method further comprises thermally bonding the unitary film to the plurality of electrically conductive elements and/or the surface of the solar cell.

The method of thermally bonding the unitary film to the plurality of elements and/or the surface of the solar cell may comprise heating the unitary film using at least one of an infrared lamp, a convection heating element, a hot air blower or an induction heating element.

The method may comprise a first method step of thermally bonding the unitary film to the plurality of electrically conductive elements and a second method step of thermally bonding the unitary film to the solar cell (e.g., a surface of the solar cell).

The method may comprise, prior to thermally bonding the unitary film to the plurality of electrically conductive elements heating the unitary film to a pre-bonding temperature corresponding to the temperature of the first endothermic peak.

As described above, at least one, or each, of the plurality of electrically conductive elements may be thermally bonded to the unitary film, when in use. The unitary film may be further configured to attach the conductive elements to the solar cell surface (e.g., to provide a mechanical connection between the conductive elements and the solar cell). The unitary film may be configured to maintain the lateral spacing the conductive elements, such that the conductive elements are correctly aligned on the solar cell surface. In an exemplary arrangement, the unitary film may not cover all the respective front and/or back surface(s) of the solar cell on to which it is overlaid.

The method may comprise heating and/or applying pressure to the unitary film (e.g. laminating) to adhere the unitary film to the electrically conductive elements and/or the surface of the solar cell. The method may comprise attaching the unitary film to the conductive elements prior to overlaying, and/or attaching, the conductive elements to the solar cells. The method of attaching the unitary film to the conductive elements may be performed during the method of coupling the associated conductive elements to the surfaces of the solar cells. In this way, the method of attaching the film to the conductive elements (e.g. the application of heat and/or pressure to the film) may also comprise attaching the film to an associated surface of the solar cell.

During fabrication of the solar cell assembly, heat and/or pressure may be applied to the unitary film so that the polymeric material softens to enable adherence of the unitary film to the conductive elements due to an application of force. In this way, the conductive elements may be at least partially embedded in the unitary film. At least a portion of the surface of each conductive element may remain exposed to enable an electrical connection to be formed with a respective surface of the solar cell.

The unitary film may be configured to provide structural support for the electrically conductive elements when the conductive elements are being handled, for example, prior to being arranged onto the solar cell. The unitary film may be configured such that at least a portion of at least one of the conductive elements is exposed from the film to form an electrical contact with the respective surface of the solar cell.

When the electrode assembly is installed on the solar cell surface, the unitary film may deform to conform to the shape of the conductive elements sandwiched between the unitary film and the solar cell. In other words, the surface of the unitary film may form ridges/protuberances over the conductive elements and may be substantially planar in regions with no conductive elements. In this way, the unitary film may comprise a conductive element contacting region which has a non-planar profile.

According to an exemplary arrangement, the solar cell assembly may comprise a first solar cell and a second solar cell. The electrode assembly may be configured to electrically connect the first solar cell to the second solar cell. In particular, the at least one electrically conductive element may be configured to electrically couple a front surface of the first solar cell with a back surface of the second solar cell.

The method may comprise arranging the second solar cell so that its back-surface faces in a substantially upward direction (e.g., vertically upward). The method may further comprise overlaying a first section of the electrode assembly onto the back surface of the second solar cell such that the second surface of the at least one electrically conductive element is arranged in contact with the back surface. The method may further comprise connecting (e.g. electrically and/or mechanically) the second surface of the at least one conductive element onto the back surface of the second solar cell. The method may comprise overlaying the front surface of the first solar cell onto a second portion of the electrode assembly such that the first surface of the at least one conductive element is arranged in contact with the front surface. The method may further comprise connecting (e.g. electrically and/or mechanically) the first surface of the at least one conductive element onto the front surface of the first solar cell.

The solar cells may each comprise a back (e.g. backmost) surface and a front (e.g. frontmost) surface being opposite the back surface. Accordingly, the method may comprise arranging a portion of the electrode assembly onto the back surface of the second solar cell to define a back connector. The method may further comprise arranging another portion of the electrode assembly onto the front surface of the first solar cell to define a front connector.

The conductive elements may be coated in a solderable material which has a melting point which is lower than the materials from which the conductive elements are formed.

The method may comprise applying heat and/or pressure to (e.g. soldering) the first portion of the electrically conductive elements (i.e. of the front connector) to form an electrical contact with the conductive surface of the first solar cell (e.g. the finger electrode), upon which the conductive element is overlaid. The method may comprise applying heat and/or pressure (e.g. soldering) the second portion of the conductive elements (i.e. of the back connector) to form an electrical contact with the conductive surface of the second solar cell (e.g. the finger electrode), upon which the conductive element is overlaid.

The method may comprise first attaching one of the front and back connectors to the respective first and second solar cells, then attaching the other of the front and back connectors to the other of the respective first and second solar cells.

The method may further comprise arranging (e.g. depositing) a plurality of finger electrodes on at least one, or each, of the front and back surfaces of the first and second solar cells. It will be understood that the method of arranging the finger electrodes may be performed prior to connecting the electrode assembly to the solar cells. The finger electrodes may be formed using a printed material, which enables it to be conveniently deposited onto the surfaces of the solar cells. The printed material may be formed using a printable precursor, such as a conductive paste which may comprise a mixture of metal powder (e.g. Ag, Al, Au powder) and an organic binder (e.g., an epoxy). The printable precursor/conductive paste may be fired, or cured, to form the printed finger electrodes. Alternatively, the finger electrodes may be deposited by various other methods including evaporation, plating, printing etc. The front and back finger electrodes may be deposited simultaneously (i.e. using a single deposition process) or they be deposited separately.

It will be understood that the terms ‘conductive’ and ‘insulating’ as used herein, are expressly intended to mean electrically conductive and electrically insulating, respectively. The meaning of these terms will be particularly apparent in view of the technical context of the disclosure, being that of photovoltaic solar cell devices. It will also be understood that the term ‘electrical contact’ is intended to mean a non-rectifying electrical junction (i.e. a junction between two conductors which exhibits a substantially linear current-voltage (I-V) characteristic).

The skilled person will appreciate that except where mutually exclusive, a feature or parameter described in relation to any one of the above aspects may be applied to any other aspect. Furthermore, except where mutually exclusive, any feature or parameter described herein may be applied to any aspect and/or combined with any other feature or parameter described herein.

### BRIEF DESCRIPTION OF THE DRAWINGS

Embodiments will now be described by way of example only, with reference to the Figures, in which:

FIG. 1 is a close-up sectional side view of a solar module including a solar cell assembly, the solar cell assembly comprising a first solar cell coupled to a second solar cell by an electrode assembly;

FIGS. 2A and 2C are plan views of the top (front) and bottom (back) of the first and second solar cells, respectively, as shown in FIG. 1, respectively;

FIGS. 2B and 2D are transverse sectional views taken through the first and second solar cells, respectively, as shown in FIGS. 2A and 2C;

FIGS. 3 to 8 are side views of a solar cell assembly, showing the different stages of a method of manufacturing the solar cell assembly;

FIG. 9 is a flowchart illustrating a method of manufacturing the solar cell assembly, as shown in FIGS. 3 to 8;

FIG. 10 is a schematic of a differential scanning calorimeter for determining thermal transitions in a material;

FIG. 11 is a flowchart illustrating a method of determining the characteristic properties of a polymeric material of a unitary film for an electrode assembly of a solar cell;

FIGS. 12 to 17 are differential scanning calorimeter traces of different polymeric materials determined using the calorimeter as shown in FIG. 10, and according to the method as shown in FIG. 11;

FIGS. 18 and 19 are schematics of a 180-degree peel tester for determining the peel strength of a polymeric unitary film;

FIG. 20 is a flowchart illustrating a method of determining the peel strength of a unitary film for an electrode assembly of a solar cell; and

FIGS. 21 and 22 are peel-force traces of different polymeric materials determined using the 180-degree peel tester as shown in FIGS. 18 and 19, and according to the method as shown in FIG. 20.

### DETAILED DESCRIPTION

Aspects and embodiments of the present disclosure will now be discussed with reference to the accompanying figures. Further aspects and embodiments will be apparent to those skilled in the art.

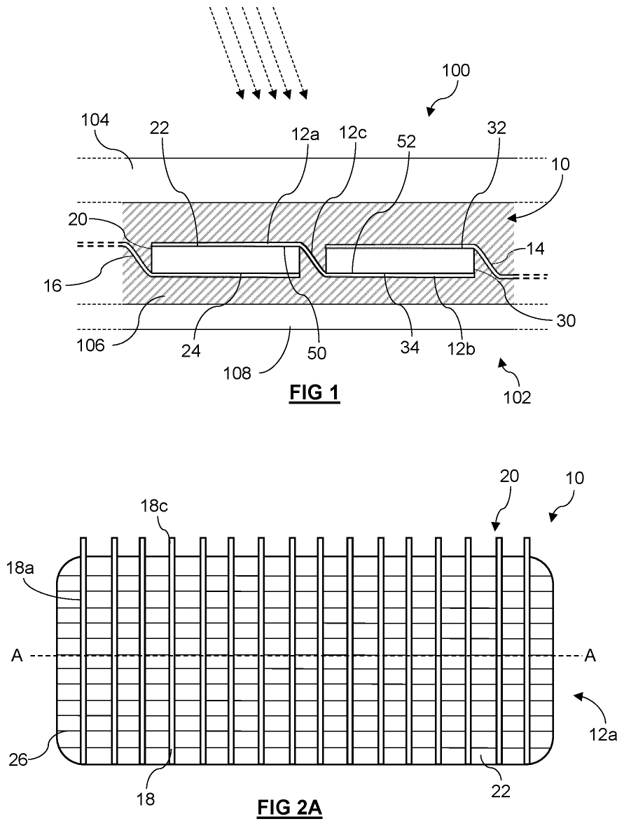

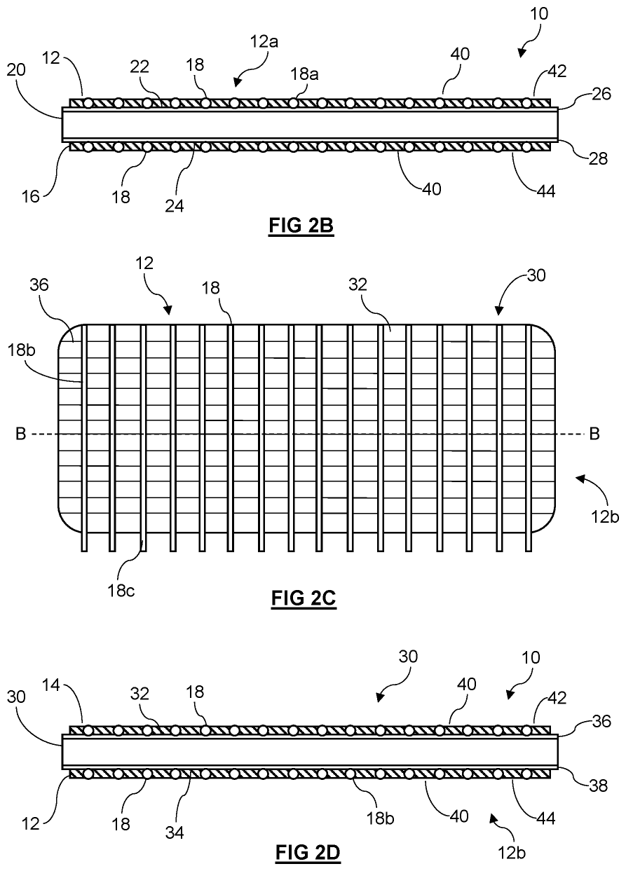

An exemplary solar cell assembly 10 as manufactured according to a method of the present disclosure, will be described with reference to FIGS. 1 and 2A-2D. In the drawings, the thickness of layers, films, elements etc., are exaggerated for clarity. Furthermore, it will be understood that when an element such as a layer, film, region, or substrate is referred to as being “on” another element, it can be directly on the other element or intervening elements may also be present. In contrast, when an element is referred to as being “directly on” another element, there are no intervening elements present.

FIG. 1 shows the solar cell assembly 10 arranged within a support assembly 102 of a solar module 100 (e.g. a solar panel). The solar cell assembly 10 includes a first solar cell 20, a second solar cell 30 and an electrode assembly 12 which is arranged to electrically couple a front surface 22 of the first solar cell 20 to a back surface 34 of the second solar cell 30.

The electrode assembly 12 comprises a plurality of conductive elements which are configured to provide an improved electrical pathway between the first and second solar cells 20, 30, whilst also enhancing the light scattering and absorption conditions at the front surface 22 of the first solar cell 20.

A first portion of the electrode assembly 12 is arranged to contact the front surface 22 of the first solar cell 20 to define a front connecting portion, or front connector 12a, of the electrode assembly 12. A second portion of the electrode assembly 12 contacts the back surface 34 of the second solar cell 30 to define a back connecting portion, or back connector 12b, of the electrode assembly 12. The first and second connectors 12a, 12b are electrically coupled together by a third interconnecting portion 12c which bends between the respective front and back surfaces 22, 34 of the adjacently positioned solar cells 20, 30 of the solar cell assembly 10.

The solar cell assembly 10 is one of a plurality of solar cell assemblies which are arranged within the support assembly 102. For example, a front surface 32 of the second solar cell 30 is electrically coupled to the back surface of a third solar cell (not shown) by a second electrode assembly 14. Also, a third electrode assembly 16 is provided to couple a back surface 24 of the first solar cell 20 to the front surface of a fourth solar cell (not shown).

It will be understood, for example, that the second and third solar cells in this arrangement are electrically coupled together by the second electrode assembly 14 to define a second solar cell assembly. The plurality of solar cells 20, 30 are thereby coupled together by the electrode assemblies 12, 14, 16 to define a single string.

A front plate 104 of the support assembly 102 comprises a transparent (e.g. glass) sheet which is configured to allow light to pass through into a central chamber 106 in which the solar cell assembly 10 is mounted. The arrows at the top of FIG. 1 show the direction of the solar radiation which is incident upon the solar cell assembly 10.

A back plate 108 of the support assembly 102 is arranged to enclose the solar cell assembly 10 within the central chamber 106. The back plate 108 comprises a reflective sheet which is configured to reflect any light which is incident upon its upper surface, back towards the solar cell assembly 10. The central chamber 106 is filled with an encapsulating material (the shaded area shown in FIG. 1) which prevents ingress of external liquid or gaseous entrants.

FIGS. 2A and 2C illustrate the top (front) and bottom (back) view of the first and second solar cells 20, 30, respectively, of the solar cell assembly 10. FIGS. 2B and 2D show transverse sectional views of the first and second solar cells 20, 30, respectively, taken along the dashed lines A-A and B-B, as shown in FIGS. 2A and 2C.

Each of the solar cells 20, 30 has a length which is the vertical dimension of FIGS. 2A and 2C, and a width which is the horizontal dimension of FIGS. 2A and 2C. The first and second solar cells 20, 30 are arranged in a common transverse plane (as shown in FIG. 1) such that their widthwise and lengthwise dimensions lie in parallel with each other. Each of the front surfaces 22, 32 of the respective solar cells define a surface on which light is incident when the solar cell assembly 10 is in use. The back surfaces 24, 34 each define a surface which is opposite to the respective front surface 22, 32, as shown in FIGS. 2B, 2D.

Each solar cell 20, 30 includes a layered structure (not shown) arranged between its respective front and back surfaces. The layered structure is a multi-layer semiconductor assembly which includes a photovoltaic element (or layer) which is configured to generate electrical charge carriers from the absorption of incident radiation. The front and back finger electrodes 26, 36, 28, 38 are each configured to conduct away the electrical charge carriers generated by the respective solar cell 20, 30.

The first solar cell 20 includes a first plurality of finger electrodes 26 arranged on its front surface 22 (i.e. front finger electrodes), and a second plurality of finger electrodes 28 arranged on its back surface 24 (i.e. back finger electrodes). Similar, the second solar cell 30 includes a first plurality of finger electrodes 36 arranged on its front surface 32, and a second plurality of finger electrodes 38 arranged on its back surface 34.

The electrode assembly 12 comprises a plurality of conductive elements 18, as shown in FIGS. 2A to 2D. The conductive elements 18 are configured to form an electrical contact with finger electrodes 26, 38 arranged on the front and back surfaces 22, 34 of the first and second solar cells, respectively. The conductive elements 18 each have an integral elongate form, such as a wire, which is formed of an electrically conductive material. For example, the conductive elements 18 comprise a metallic alloy material, which includes at least one of Ag, Al, Au and Cu. The conductive elements 18 are each arranged within an optically transparent insulating film 40, as shown most clearly in FIGS. 2B and 2D.

A first portion 18a of the plurality of conductive elements 18 defines the front connector 12a of the electrode assembly 12. A second portion 18b of the plurality of conductive elements 18 defines the back connector 12b of the electrode assembly 12. Accordingly, each of the plurality of conductive elements 18 extends from the front connector 12a to the back connector 12b of the electrode assembly 12. A third portion 18c of the plurality of conductive elements 18 is configured to electrically couple together the respective first and second portions 12a, 12b.

Each of the conductive elements 18 defines a current collector of the electrode assembly 12. Furthermore, the conductive elements 18 are configured to collect charge carriers from the front finger electrodes 26 of the first solar cell 20 and transport them to the back-finger electrodes 38 of the second solar cell 30, or vice versa. Each of the conductive elements 18 comprises a width, length, and depth. The length of each conductive elements 18 defines an axial length which is substantially greater than its width and depth.

With reference to FIGS. 2A to 2D, the arrangement of each of the pluralities of finger electrodes 26, 28, 36, 38 and conductive elements 18 will now be described in more detail.

The pluralities of front and back finger electrodes 26, 28, 36, 38 are arranged to extend across the solar cells 20, 30 in the transverse direction (the horizontal direction in FIGS. 2A, 2C) and are equally spaced apart in the longitudinal direction (the vertical direction in FIGS. 2A, 2C). The dimensions of each finger electrode 26, 28, 36, 38 are substantially the same as that of every other finger electrode 26, 28, 36, 38. Furthermore, each of the finger electrodes has a rectangular cross-section (which is measured perpendicular to the electrode's length).

The finger electrodes arranged on each of the front and back surfaces 26, 28, 36, 38 of the solar cells 20, 30 are aligned in parallel with each other, and with a corresponding finger electrode on the opposite side of the solar cell. As shown in FIGS. 2A and 2C, each of the pluralities of front and back finger electrodes 26, 28, 36, 38 comprises twelve electrodes.

The finger electrodes 26, 28, 36, 38 are formed of an electrically conductive material, which is formed of a metallic alloy comprising Ag. It will be understood that the electrically conductive material is a printed material, which enables the finger electrodes to be conveniently deposited onto the respective surfaces of the solar cells.

The first and second portions 18a, 18b of the plurality of conductive elements 18 are parallel and extend lengthwise relative to the front and back surfaces 22, 34 of the solar cells, in a longitudinal direction (the vertical direction in FIG. 2A). The conductive elements 18 are also equally spaced apart in a transverse direction relative to the front and back surfaces 22, 34 (the horizontal direction in FIG. 2A) to define longitudinal-extending spaces between the conductive elements 18. Accordingly, each one of the first and second portions 18a, 18b defines an array of parallel, transversely spaced conductive elements 18.

Each of the first portions 18a of the plurality of conductive elements 18 are axially aligned with the corresponding second portions 18b of the conductive elements 18 of the same electrode assembly 12. Also, the second portions 18b of conductive elements 18 of the first electrode assembly 12 are axially aligned with the first portions 18a of the conductive elements 18 of the second electrode assembly 14, with the second solar cell 30 interposed between. Accordingly, the pluralities of front and back finger electrodes 26, 38 are arranged perpendicular to the first and second portions 18a, 18b of the plurality of conductive elements 18, as shown in FIGS. 2A and 2C.

The number of conductive elements 18 of the electrode assembly 12 is between 4 and 20. According to the embodiment described herein the first electrode assembly 12 has sixteen conductive elements 18, as shown in FIGS. 2A to 2D. It will be appreciated that, in some other embodiments, a different number of conductive elements and/or finger electrodes may be present, without departing from the scope of the present invention.

The conductive elements 18 each have a circular transverse cross-sectional shape (i.e. transverse to the axial length of the conductive element 18), as shown in FIGS. 2B and 2D. However, the conductive elements 18 may be configured with different cross-sectional shapes, without departing from the scope of the present invention.

Each of the conductive elements 18 comprises a first surface 50 which is configured to electrically contact the front surface 22 of the first solar cell 20, as shown in FIG. 1. Each conductive element 18 also comprises a second surface 52 configured to electrically contact the back surface 34 of the second solar cell 30, as shown in FIG. 1.

Each of the conductive elements 18 is formed from a single wire portion (i.e. the first and second portions 18a, 18b of each conductive element 18 are integrally formed with each other). In this way, the conductive elements 18 provide a direct electrical connection between the first and second solar cells 20, 30, which increases the flow of current therebetween. The plurality of conductive elements 18 are covered in a coating (not shown) which is configured, when in use, to solder the respective first and second surfaces 50, 52 to a respective surface of the solar cells 20, 30 upon which they are overlaid. The coating is an electrically conductive material having a melting point which is lower than that of the conductive element 18.

It will be appreciated that FIGS. 2A and 2B shows the first portion 18a of the conductive elements 18 on the front surface 22 of the first solar cell 20 (i.e. the front connector 12a of the electrode assembly 12), whereas FIGS. 2C and 2D show the second portion 18b of the same conductive elements 18 on the back surface 34 of the second solar cell 30 (i.e. the back connector 12b of the electrode assembly 12).

As described above, the electrode assembly 12 comprises an insulating and optically transparent film 40 which is thermally bonded to the conductive elements 18. In general, the film has a unitary construction (i.e. it is formed of a single layer of material, not a plurality of discrete layers), and is formed of a polymeric material. Certain characteristic properties of the polymeric material which determine how the unitary film 40 adheres to the conductive elements, and/or the solar cell surfaces, can be determined using differential scanning calorimetry (DSC) analysis, as will be described in more detail below.

The polymeric material may be formed from a polymer resin which comprises at least one of a polyolefin elastomer (POE), polyvinylbutyral (PVB) hydrocarbon ionomer, thermoplastic organo-silicon, silicon rubber, polyurethane, thermoplastic silicone elastomer (TPSE) and ethylene-vinyl acetate (EVA). The polymeric material is selected to encompass the following characteristics: high ductility, low electrical conductivity, high optical transparency, thermal stability, and resistance to shrinkage.

The unitary film is configured with a haze parameter of less than 35%, alternatively up to 25%, optionally up to 18%.

It will be understood that the haze parameter of a polymeric material may be defined as a measure of the proportion of incident light which is scattered by more than 2.5°, as measured by a spectrophotometer.

The unitary film is configured to transmit at least 85% of incident light having a wavelength of between 280 nm and 1100 nm.

The unitary film has a thickness of at least 25 μm, optionally at least 55 μm and/or up to 180 μm. The front and back film portions 42, 44 are thinner than the conductive elements 18. For example, the conductive elements 18 have a thickness of between 200 μm and 300 μm.

The first and second portions 18a, 18b of the plurality of conductive elements 18 are each arranged in separate film portions, which are arranged on the front and back surfaces 22, 34 of the respective solar cells. For example, the front connector 12a comprises a first film portion which defines a front film portion 42 and the back connector 12b comprises a second film portion which defines a back-film portion 44. However, it is noted that the conductive elements 18 in the third portion 18c are free from any film covering.

According to an exemplary arrangement of the solar cell assembly 10, each of the first and second portions 18a, 18b of the conductive elements 18 is attached to a surface of the respective unitary film portions 42, 44 that faces the solar cell. Accordingly, the “solar cell-facing” surfaces of each unitary film portion 42, 44 is thermally bonded to the respective surfaces 22, 34 of the first and second solar cells 20, 30.

With reference to FIGS. 2B and 2D, in the case of the front connector 12a, the film 42 is arranged to contact the front surface 22 of the solar cell in the areas in-between the conductive elements 18 and the front finger electrodes 26. The back-film portion 44 is configured in the same way for the back connector 12b. Each of the films 42, 44 is configured to at least partially (e.g. completely) envelope, or surround, the respective conductive elements 18 and the respective finger electrodes 26, 38, as shown in FIGS. 2B and 2D.

The front and back film portions 42, 44 are arranged to provide adhesion between the solar cells and the conductive elements 18 so that the conductive elements are correctly arranged on the solar cells (i.e. aligned with the finger electrodes). In an exemplary embodiment, the front and back film portions 42, 44 may not fully cover the respective surfaces of the solar cells.

Whilst the front and back film portions 42, 44 shown in the drawings comprise substantially planar bottom and top surfaces, respectively. It will be understood that the films may be configured to conform to the structural components of solar cells and/or conductive elements. For example, the film 40 may be comprised of elongate channels recessed towards the solar cell in the regions of the back surface 34 in-between conductive elements, and may form ridges/protuberances over the structures electrodes (e.g. finger electrodes and conductive elements) where they are present.

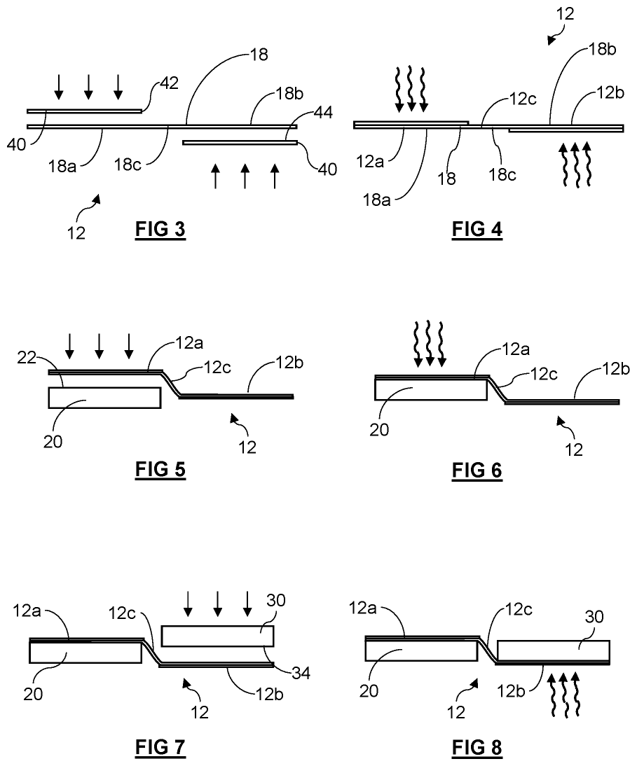

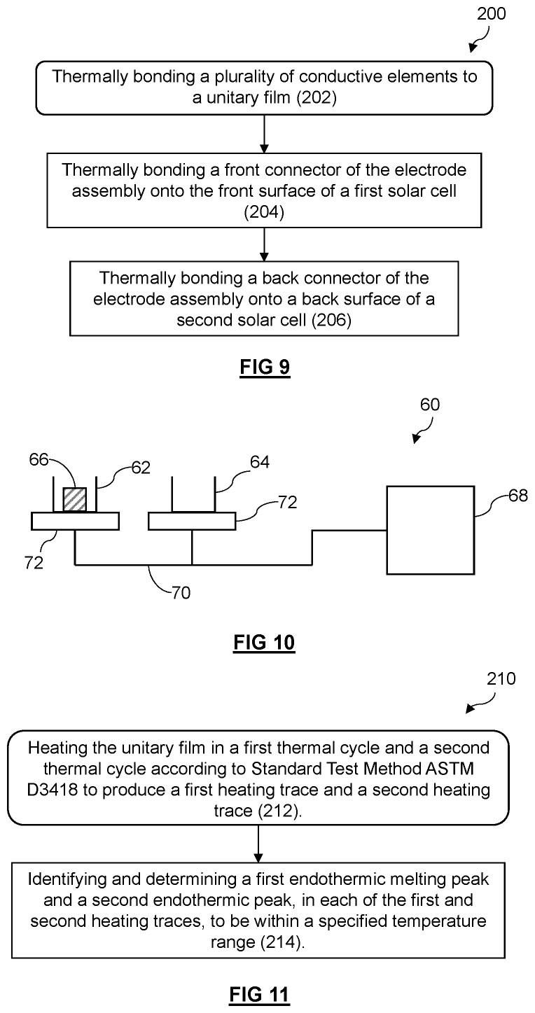

An exemplary method of manufacturing the solar cell assembly 10 will now be described with reference to FIGS. 3 to 8, which illustrate the steps of the manufacturing method. Reference will also be made to FIG. 9 which shows a flow chart of the corresponding method steps.

The method commences with a first method step 202 in which a plurality of conductive elements 18 are thermally bonded to a unitary film 40 to form the electrode assembly 12. As described above, the unitary film 40 comprises separate first and second film portions 40a, 40b. As shown in FIGS. 3 and 4, the method comprises arranging the first portion 18a of the plurality of conductive elements 18 onto the first unitary film portion 40a to define the front connector 12a of the electrode assembly 12. The method further includes arranging the second unitary film portion 42 onto the second portion 18b of the plurality of conductive elements 18 to define the back portion 12b of the electrode assembly 12.

Heat and pressure are applied to the unitary film portions 42, 44, as shown in FIG. 4, which causes the film's polymeric material to soften, and thereby adheres the film portions to the conductive elements 18. This results in the conductive elements 18 being at least partially embedded in the unitary film portions 42, 44, such that at least a portion of each conductive element remains exposed so as to form an electrical contact with the respective solar cells 20, 30. The unitary film 40 is heated using an infrared lamp (not shown). Alternatively, the required heat may be applied by any suitable heating means, such as a convection heating element, a hot air blower or an induction heating element. The heating means is configurable to control the temperature of the unitary film 40 during the bonding process, as will be explained in more detail below.

It will be understood that the first and second portions 18a, 18b, of the plurality of conductive elements 18 can be attached to the respective unitary film portions 42, 44 at the same time, or during separate processes. When the electrode assembly 12 is in use, the first portion 18a of the plurality of conductive elements defines a front connector 12a of the electrode assembly 12, whereas the second conductive element portions 18b defines a back connector 12a. Similarly, the first and second unitary film portions 42, 44 define front and back unitary film portions, respectively.

In a second method step 204, a first solar cell 20 is thermally bonded to the front connector 12a of the electrode assembly 12. The conductive elements' first portions 18a are brought into contact with the front surface 22 of the first solar cell 20, as shown in FIG. 5. The conductive elements of the front connector 12a are overlaid onto the front surface 22 of the first solar cell 22 such that they sit perpendicular to the front finger electrodes, as shown in FIG. 2A. The method further involves heating and/or applying pressure to the conductive elements 18 of the front connector 12a to physically bond them to the first solar cell's front surface 22 under a compressive force, as illustrated in FIG. 6. The application of heat and pressure also laminates the front unitary film portion 42 onto the front surface 22 of the first solar cell 20.

In a third method step 206, a second solar cell 30 is thermally bonded to the back connector 12b of the electrode 12, as shown in FIGS. 7 and 8. The method comprises overlaying the back connector 12b onto the back surface 34 of the second solar cell 30 such that they sit perpendicular to the finger electrodes 38, as shown in FIG. 2D. The third method step 206 further involves heating and/or applying pressure to the conductive elements 18 in the second connector 12b to bond the electrode assembly 12 the second solar cell's back surface 34 under a compressive force, as illustrated in FIG. 8. The application of heat and pressure also laminates the back unitary film portion 44 onto the back surface 34 of the second solar cell 30.

During the second and third method steps 204, 206, the application of heat and pressure causes the coating on the conductive elements 18 to melt and flow towards the finger electrodes on the respective surfaces of the solar cells 20, 30. Once the coating has cooled and solidified, it forms an electrical contact with the underlying finger electrodes 38, as shown in FIGS. 2B and 2D.

As a result of the above described method, the front and back connectors 12a, 12b of the electrode assembly 12 are both mechanically and electrically coupled to the respective first and second solar cells 20, 30 to form a solar cell assembly 10 according to the present invention.

It will be appreciated that at least some of the above described method steps may be undertaken concurrently or in any order. For example, the front and back connectors 12a, 12b may also be connected to the respective front and back surfaces 22, 34 of the first and second solar cells 20, 30 at the same time.

Prior to at least the second method step 204, the solar cells are manufactured in a conventional manner as would be understood by the person having ordinary skill in the art. In particular, the method includes configuring each of the solar cells with a conductive surface (or conductive portion) on their respective front and back surfaces, e.g. to form the pluralities of front and back finger electrodes 36, 38, respectively. The finger electrodes 36, 38 are deposited onto their respective surfaces using a screen-printing process, as would be understood by the skilled person. Once the plurality of finger electrodes 36, 38 are deposited onto the surfaces of the first and second solar cells 20, 30, the electrode assembly 12 can be connected to the solar cells 20, 30 to define a solar assembly 10.

As described above, the material of the unitary film 40 (e.g. the front and back unitary film portions 42, 44) is a polymeric material. The polymeric material of the unitary film 40 is characterised by determining its physical properties according to a set of criteria. In particular, a first criterion and a second criterion can be used, respectively, to determine the thermal and peel-force properties of the unitary film 40.

### First Criterion of the Unitary Film

The first criterion is used to determine that the polymeric material has at least two endothermic peaks at a temperature between 40° C. and 200° C. measured by differential scanning calorimetry (DSC).

The DSC testing method of the first criterion involves heating up, and/or cooling down, a sample of the polymeric material and measuring over time the heat flowing towards (and/or away from) the material to identify and measure the endothermic peaks. The analysis is carried out using a differential scanning calorimeter 60, as shown in FIG. 10. It will be understood that an endothermic peak corresponds to a thermal transition of a polymeric material.

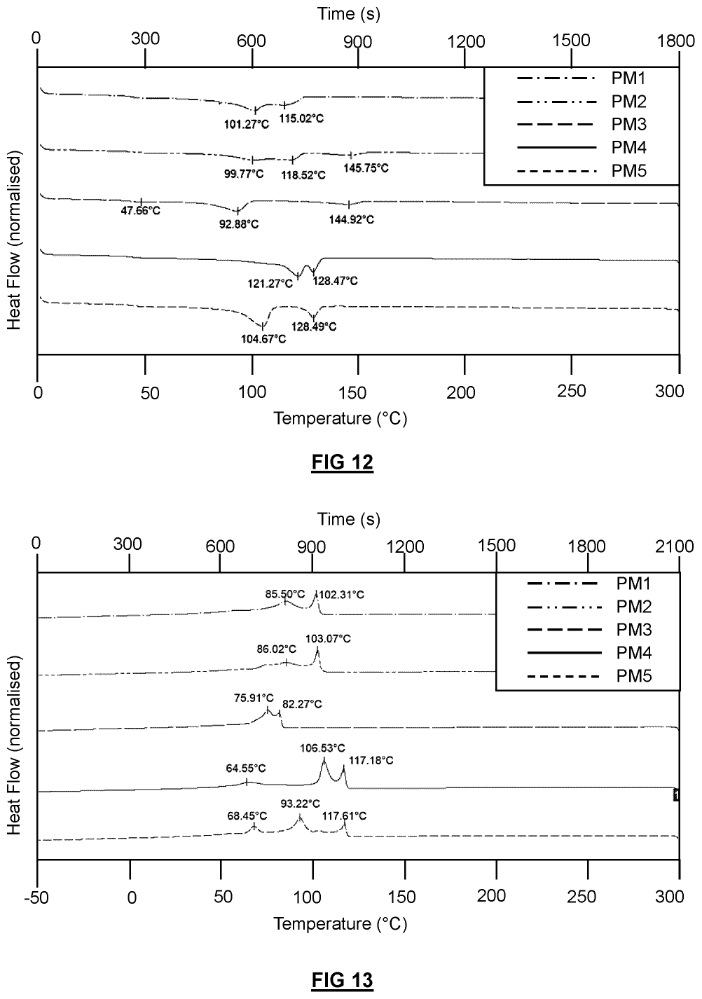

An exemplary DSC testing method 210, according to the first criterion of the unitary film 40, will now be described with reference to FIG. 11, which shows a flow chart of the corresponding method steps. Also, reference will be made to FIG. 10, which shows a schematic of a calorimeter 60 used to test polymeric materials, and FIGS. 12 to 17 which show heating and cooling traces of a variety of different polymeric materials under investigation. The DSC testing method 210 is used to identify and determine whether a polymeric material meets the required thermal properties for the unitary film 40.

The DSC testing method 210 incorporates the Standard Test Method ASTM D3418, which is a standard test method for transition temperatures and enthalpies of fusion and crystallisation of polymers by differential scanning calorimetry. The DSC testing method 210 includes a first method step 212 which involves performing a first thermal cycle and a second thermal cycle on a sample of polymeric material 66 of the unitary film 40. The first and second thermal cycles are performed sequentially according to Standard Test Method ASTM D3418.

The first thermal cycle comprises a heating stage in which the sample is heated gradually from 0° C. 300° C. at a heating rate of 10°/min. The heating stage of the first thermal cycle removes the sample's thermomechanical history, which may result from the manufacturing processes used to make the film. After the heating stage of the first thermal cycle is complete, the material sample 66 is held by the calorimeter 60 at a holding temperature of 300° C. for 5 minutes.

Method step 212 involves placing the polymeric material sample 66 in a test cell 62 which is thermally coupled by a connector 70 to an empty reference cell 64. A control module 68 of the calorimeter 60 is configured to control a pair of electric heating elements 72, to control the temperature and heating rate of the test and reference cells 62, 64.

During the DSC analysis, the control module 68 monitors the heat flow between the test cell 62 and the reference cell 64 as both the cells are heated up. The measured DSC data is outputted in the form a trace (e.g., a heating trace) of heat flow (W/g) plotted against either temperature (C) and/or time(s), as shown in FIG. 12.

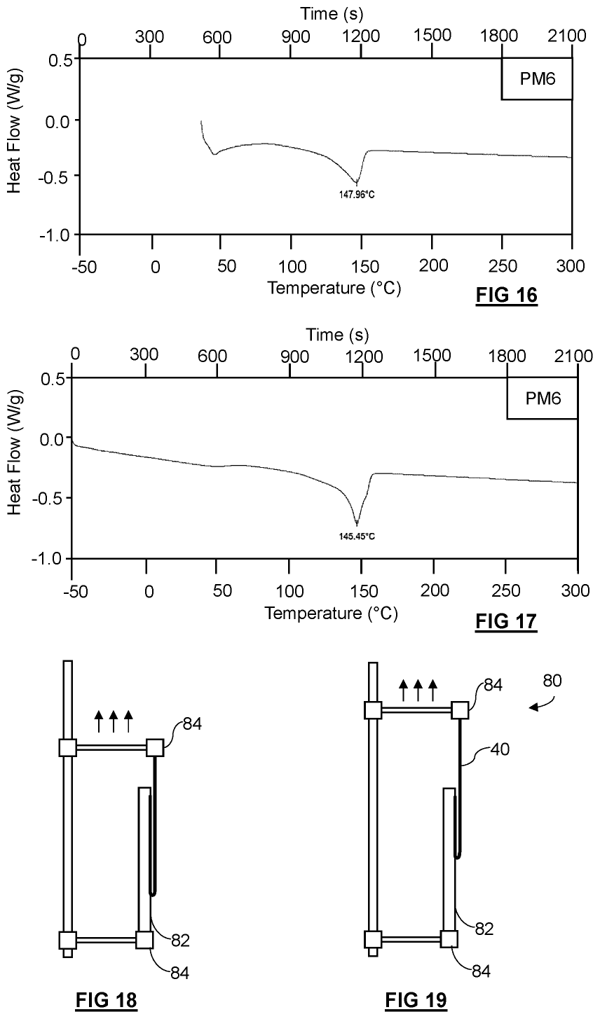

The heat flow represents the power per unit mass (W/g) flowing between the test and reference cells 62, 64. It will be understood that in FIGS. 12 to 15, the y-axis has been normalised in order to show multiple traces on the same set of axes, whereas in FIGS. 16 and 17 the heat flow values are shown in units of W/g. The temperature values on the lower x-axis shown in FIGS. 12 to 17 correspond to the temperature (° C.) of the test and reference cells 62, 64. The time values shown on the upper x-axis represent the duration of the DSC analysis, as measured in seconds(s).

The first thermal cycle also includes a cooling stage which sequentially follows the heating stage. The cooling stage involves cooling the polymeric material sample 66 from 300° C. at a rate of 10°/min to a temperature of −50° C. During the cooling stage, the control module 68 monitors the heat flow between the test and reference cells 62, 64 and outputs a cooling trace of heat flow (W/g) vs temperature (° C.) and/or time(s), as shown in FIG. 13. Once the cooling stage is complete, the material sample 66 is held by the calorimeter 60 at a holding temperature of −50° C. for 5 minutes.

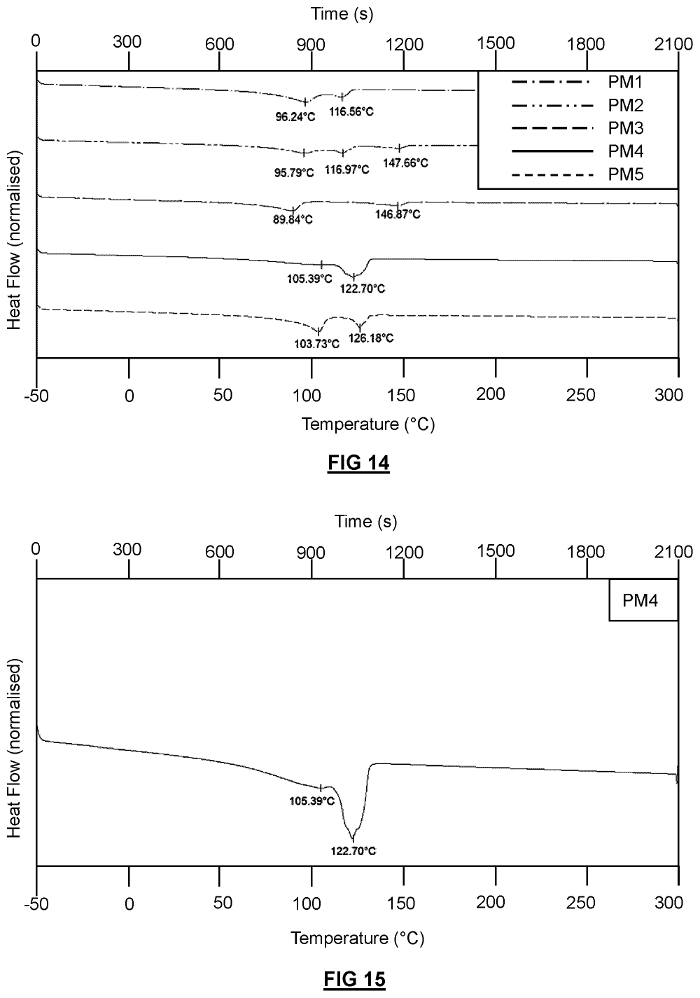

Once the 5 minutes has elapsed, the method step 212 commences by performing the second thermal cycle on the sample 66. The second thermal cycle includes a heating stage in which the sample 66 is heated gradually from −50° C. to 300° C., at a heating rate of 10°/min. As with first thermal cycle, the control module 68 monitors the test and reference cells 62, 64 throughout the second heating stage and outputs a second heating trace, as shown in FIGS. 14 and 15.

Accordingly, the first heating trace is measured during the heating stage of the first thermal cycle and the second heating trace is determined during the heating stage of the second thermal cycle.

Throughout the various DSC analyses (e.g., the heating and cooling stages of the first and second thermal cycles), the polymeric material sample 66 is held in an inert atmosphere (e.g. a nitrogen atmosphere) to prevent the material sample 66 from reacting with the atmosphere, (e.g. oxidising). According to an exemplary method, the calorimeter 60 is purged with nitrogen gas at a purge flow rate of 50 mL/min.

The DSC traces for six exemplary polymeric materials (PM1-6) are shown in FIGS. 12 to 17. The traces shown in FIGS. 12 and 16 correspond to the heating stage of the first thermal cycle (i.e. in which the samples are heated from 0° C. to 300° C., at a heating rate of 10°/min). The traces shown in FIG. 13 correspond to the cooling stage of the first thermal cycle (i.e. in which samples PM1-PM5 are cooled from 300° C. to −50° C., at a cooling rate of 10°/min). The traces shown in FIGS. 14, 15 and 17 correspond to the heating stage of the second thermal cycle (i.e. in which the samples are heated from −50° C. to 300° C., at a heating rate of 10°/min).

Each of the materials PM1-6 is analysed to produce a composite DSC trace including a test trace (i.e. corresponding to test cell 62), and a reference trace 64 (i.e. corresponding to the reference cell 64). The reference traces are substantially flat because there is nothing contained within the reference cell 64. Any phase transitions in the sample materials PM1-6 will appear as a peak in the test trace which deviates from the reference trace. In the case of an endothermic transition, the peak appears as a negative peak due to the heat flow absorbed by the material sample 66 in the test cell 62, as it melts.

A further method step 214 involves identifying the presence two endothermic peaks in the first and second heating traces, corresponding to the polymeric material sample 66. In particular, the method step 214 comprises identifying the presence of a first endothermic peak and a second endothermic peak in each of the first and second heating traces, and determining that the first and second endothermic peaks, in each of the first and second heating traces, are at a temperature between 40° C. and 200° C.

Identifying the presence of a peak (e.g., an endothermic peak) in the DSC trace involves identifying a region of the test trace that deviates from the reference trace to form a local minimum (i.e. a negative peak). In the case of an endothermic peak, the peak deviates below the reference trace because it corresponds with an endothermic transition in the polymeric material, which directs heat flow towards the test cell 62.

If an endothermic peak is identified, it can be characterised to determine an associated peak temperature (Tp). The peak temperature is determined by identifying a minimum heat flow value of the melting peak, i.e. a value which is less than its nearest neighbouring values. The peak temperature of the first endothermic peak (i.e. the first peak temperature) represents a characteristic temperature of endothermic which corresponds to the polymeric material under investigation.

As can be seen in each of the traces shown in FIGS. 12 and 14, there are no peaks below 40° C. and above 200° C. It can be determined from this that there are no endothermic transitions in this temperature range. Also, it is noted that the reference traces for each sample remains substantially constant across the full temperature range, as would be expected.

It is clear from the DSC traces shown in FIG. 12 that each of PM1, PM2, PM3, PM4 and PM5 has at least two endothermic peaks (e.g., first and second endothermic peaks) with corresponding first and second peak temperatures which are between 40° C. and 200° C. By contrast, PM6 only has one endothermic peak that falls within the required temperature range (i.e., 40° C. and 200° C.), as shown by the trace in FIG. 16.

In situations where more than one peak is identified in a heating trace (e.g., the first and a second endothermic peaks), the first peak corresponds to the peak which has the lowest peak temperature and the second peak represents the peak which exhibits the higher peak temperature. Similarly, if a trace has three peaks, then the third peak can be identified as having the peak temperature that is greater than that of the first and second peaks.

Consequently, the polymeric materials PM1-5 each fulfil the first criterion, as determined by DSC testing method 210, and would therefore fall within the scope of a unitary film 40 according to an aspect of the present disclosure. Furthermore, such unitary films 40 would be suitable for use in an electrode assembly and/or a solar cell assembly according to aspects of the present disclosure.

By contrast, the PM6 material does not fall within the scope of aspects of the present disclosure because the polymeric material does not meet the first criterion as determined by the DSC testing method 210.

A summary of the results of the DSC analysis of method step 214 for polymeric materials PM1-6 is presented in Table A. It is noted that each of the materials PM1-5 have at least two endothermic peaks, in each of the first and second heating traces, within a range of 40° C. to 200° C., whereas the PM6 material only has one peak (e.g., in the first and second heating traces) within the required range.

Each of the first and second endothermic peaks are clearly visible in the first and second heating traces of the materials PM1-3 and PM5, and in the first heating trace for material PM4. An enlarged version of the second heating trace for material PM4 is shown in FIG. 15, to highlight the two separate endothermic peaks 105.39° C. and 122.70° C., respectively.

TABLE A
Summary of DSC results for polymeric materials
PM1-6 (FIGS. 12, 14, 15, 16 and 17).

| | First heating trace | | | Second heating trace | | |
|---|---|---|---|---|---|---|
| | 1^{st} T_{P} | 2^{nd} T_{P} | 3^{rd} T_{P} | 1^{st} T_{P} | 2^{nd} T_{P} | 3^{rd} T_{P} |
| Material | (° C.) | (° C.) | (° C.) | (° C.) | (° C.) | (° C.) |
| PM1 | 101.27 | 115.02 | — | 96.24 | 116.56 | — |
| PM2 | 99.77 | 118.52 | 145.75 | 95.79 | 116.97 | 147.66 |
| PM3 | 47.66 | 92.88 | 144.92 | 89.84 | 146.87 | — |
| PM4 | 121.27 | 128.47 | — | 105.39 | 122.70 | — |
| PM5 | 104.67 | 128.49 | — | 103.73 | 126.18 | — |
| PM6 | 147.96 | — | — | 145.45 | — | — |

According to an alternative exemplary arrangement of the unitary film 40, the first criterion requires the presence of two separate peaks (e.g., first and second endothermic peaks), in the first heating trace, within a temperature range of between 80° C. and 160° C. As can be seen from Table A (and FIG. 12), each of the materials PM1-5 satisfy this criterion, because each of the traces show two separate endothermic peaks within the required temperature range. Consequently, a unitary film 40 which is formed of these polymeric materials will exhibit particularly beneficial adhesion properties when used as a foil for a solar cell electrode assembly 12.

A further condition of the first criterion is that the second heating trace has two distinct endothermic peaks (e.g., a first endothermic peak and a second endothermic peak) within a temperature of between 80° C. and 160° C. Once again, each of the materials PM1-5 satisfies this criterion, as shown in Table A above. However, material PM6 does not satisfy the criterion (e.g., because it only has one endothermic peak, 145.45° C., within the required range).

A further requirement of the first criterion is that at least one (e.g., the first endothermic peak) in each of the first and second heating traces is between 40° C. and 130° C. This is the case with each of materials PM1-5, but not PM6. Hence, PM6 does not satisfy the condition, and does not fall within the scope of the unitary film 40 according to the present disclosure.

An additional exemplary condition of the first criterion is that the second heating trace has an endothermic peak (e.g., the first endothermic peak described above) which is at a temperature between 80° C. and 130° C. In addition, each of the first and second heating traces may be required to include at least one further endothermic peak (e.g., the second and/or third endothermic peaks as described above) between 100° C. and 160° C. Furthermore, a requirement of the first criterion may be that the at least one further endothermic peak in the first heating trace is between 100° C. and 145° C. Each of the materials PM1-5 satisfy each of these conditions, and would therefore fall within the scope of the unitary film 40 according to the present disclosure.

According to an alternative exemplary condition of the first criterion the further endothermic peak in the first heating trace is between 100° C. and 135° C. Each of the materials PM1, PM2, PM4 and PM5 satisfy this condition. According to a further exemplary condition of the first criterion, each of the first and second heating traces may be required to include at least one further endothermic peak (e.g., the second and/or third endothermic peaks as described above) at a temperature between 100° C. and 145° C. Each of the materials PM1, PM2, PM4 and PM5 satisfy these conditions.

The DSC testing method 210 includes further means of determining that a polymeric material (e.g. PM1-5) has the desired thermal properties for use as a unitary film 40. According to an exemplary method, the method step 214 involves identifying a third endothermic peak in each of the first and second heating traces (e.g. the third peaks present in the DSC traces for PM2, as shown in FIGS. 12 and 14). This also involves determining that the peak temperature of the third endothermic peaks (e.g. the third peak temperatures) are within the required temperature range, of between 130° C. and 200° C. The material PM2 is the only sample which exhibits a third endothermic peak in each of its first and second heating traces, as shown in Table A. Furthermore, it is noted that each of the third endothermic peaks of PM2 fall within the required temperature range. Therefore, material PM2 fulfils the requirements of the criterion, and would be preferably suited for use in a unitary film 40 according to an exemplary aspect of the present disclosure.

According to a further exemplary arrangement of the DSC testing method 210, the method step 212 involves monitoring the heat flow between the test and reference cells 62, 64 during the cooling stage of the first thermal cycle and outputting a cooling trace (as described above). The method step 214 may then comprise identifying and determining an exothermic peak at a temperature between 0° C. and 200° C.

A set of cooling traces for the polymeric materials PM1-5 is shown in FIG. 13, and a summary of the results is presented in Table B, below. From this it is clear that each of materials PM1-5 exhibit an exothermic peak within the required temperature range, and therefore satisfy the criterion.

TABLE B
Summary of DSC results for polymeric materials PM1-5 (FIG. 13).

| | First Thermal Cycle, cooling trace | | |
|---|---|---|---|
| Material | 1^{st} T_{P} (° C.) | 2^{nd} T_{P} (° C.) | 3^{rd} T_{P} (° C.) |
| PM1 | 85.50 | 102.31 | — |
| PM2 | 86.02 | 103.07 | — |
| PM3 | 75.91 | 82.27 | — |
| PM4 | 64.55 | 106.53 | 117.18 |
| PM5 | 68.45 | 93.22 | 117.61 |

A further condition of the first criterion may be that the exothermic peak is between 40° C. and 130° C. Again, each of the materials PM1-5 fulfil this requirement. As with the analysis of the first and second heating traces, the cooling trace DSC analysis may include identifying at least a second (and a third) endothermic peak which has a peak temperature within the required temperature range.

The results of the DSC testing method 210 can be used to optimise the method of manufacturing the solar cell assembly 200, as shown in FIG. 9. In particular, the manufacturing method 200 is adapted so that, prior to thermally bonding the unitary film 40 to the plurality of conductive elements 18, the unitary film 40 is heated to a pre-bonding temperature (e.g. a pre-bonding heating step) based on the DSC testing method 210. The introduction of a pre-bonding heating step into the manufacturing method 200 improves the adherence of the unitary film 40 to the plurality of conductive elements 18. The pre-bonding temperature is determined based on the first endothermic peak temperature of the first heating trace (i.e., corresponding to the heating stage of the first thermal cycle), as determined by the DSC testing method step 210.

### Second Criterion of the Unitary Film

According to the second criterion, the polymeric material of the unitary film 40 is determined to have a peel strength of at least 5 N per 10 mm width of the unitary film 40, when measured by 180-degree peel test. The peel test is used to determine (e.g., measure) the adhesion between a unitary film 40 which is thermally bonded to a surface of a substrate (e.g., the receiving surface of a solar cell). The peel test is carried out according to Standard Test Method ASTM D903 to provide a peel-force trace for each sample film under test.

The peel test method is carried out using a 180-degree peel-test apparatus 80, as shown in FIGS. 18 and 19. The peel test apparatus 80 comprises a motorised tensiometer (not shown) which is fitted with a tensile force measuring sensor (e.g., a loadcell) to determine the tensile load that is applied during testing method. The peel test apparatus 80 also includes a pair of grips 84 (or grippers) which are configured to hold the unitary film 40 and the substrate 82 during the test.

The peel test apparatus 80 also includes a controller (not shown) which is configured to operate the motorised tensiometer to move the grips (e.g., in the vertical direction as shown by the direction of the arrows in FIGS. 18 and 19). The controller is configured to control the motion of the grippers 84, which thereby determines the peel-force that is applied in order to peel the unitary film 40 from the substrate 82.

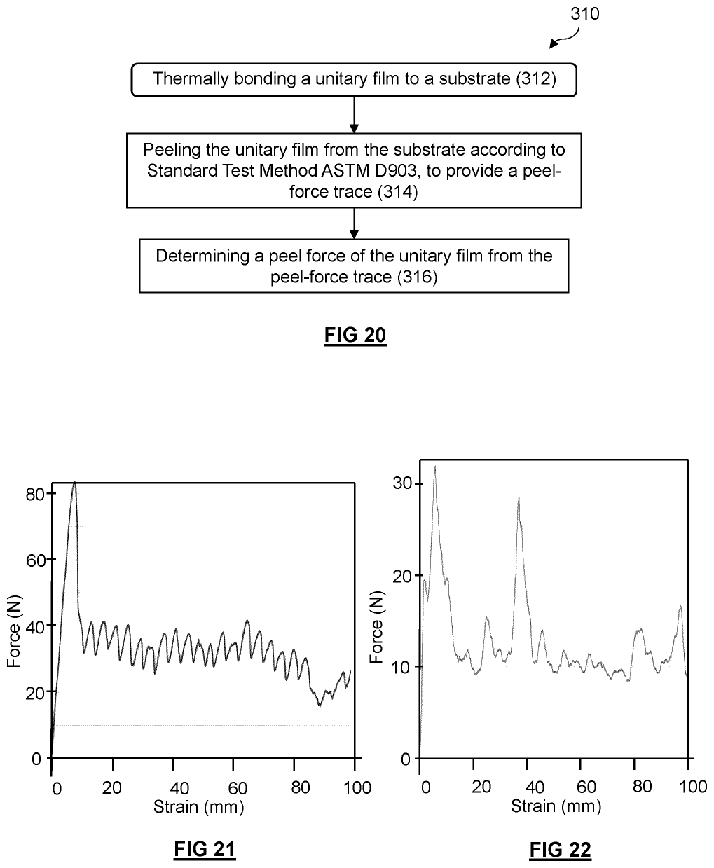

An exemplary peel test method 410, according to the second criterion of the unitary film 40, will now be described with reference to FIG. 20, which shows a flow chart of the corresponding method steps. Also, reference will be made to FIGS. 18 and 19, which shows a schematic of the testing apparatus 80 used to test a number of polymeric materials (PM1-PM6), and FIGS. 21 and 22 which show peel-force (per 10 mm width of the unitary film) traces of the different polymeric films under investigation.

In a first method step 412 the uniform film 40 is thermally bonded to the substrate 82. The substrate 82 is formed of a substantially rigid material, such as glass or metal (e.g., a metal alloy). Alternatively, the substrate 82 may be a solar cell (e.g., a crystalline silicon solar cell). The results of the presently described method (as shown in FIGS. 21 and 22 and summarised in Table C, below) were produced by peeling the unitary film 40 from the surface of a crystalline solar cell).

The method step 412 is initiated by cutting the uniform film 40 into a plurality of longitudinal strips. One end of the strip (e.g., roughly half of the total length) is arranged onto an upwardly facing surface of the substrate 82. A plurality of longitudinal strips may be arranged on a single substrate surface at the same time (e.g., to form a substantially parallel array of strips). Each longitudinal strip is arranged on the substrate such that the width of the strip is substantially perpendicular to the direction in which the peel-force will be applied.

Each strip is around 10 mm in width, and around 200 mm in length. Each strip has a thickness of at least 25 μm (e.g., around 100 μm), which is measured to be within a tolerance of +/−6 μm. The unitary film strips are each mounted on a backing sheet which provides structural support for the film during the peel test. The backing sheet has a thickness of at least 175 μm (e.g., around 185 μm) which is measured to be within a tolerance of +/−17 μm. The combined thickness of the film and backing sheet is between 200 μm and 500 μm (e.g., around 285 μm), which is measured to be within a tolerance of +/−6.

Once the strip is arranged on the surface of the substrate 82, a heat resistant sheet (e.g., formed of PTFE) is interposed between an opposing free end of the film strip, and the substrate 82. The sheet is configured to prevent adhesion between the substrate 82 and the free end of strip during the subsequent bonding method step.

Once the strips are arranged in position on the substrate's surface, they are placed in a laminator and heated to at least 50° C. Once the strips are bonded to the surface 82, they are allowed to cool for a pre-determined period (e.g., at least 30 minutes) before carrying out the peel-force analysis (e.g., before peeling the film from the substrate 82).

It will be appreciated that only a portion of each strip is thermally bonded to the substrate 82. Accordingly, each strip is configured with a free end (e.g., a non-bonded end) which can be readily coupled to a gripper 84 of the peel-test apparatus 80.

In a second method step 314, the strips of film are loaded onto the peel test apparatus and analysed to determine a characteristic peel strength for each material. The method step 314 involves firstly loading the strips and the substrate 82 into the peel-test apparatus 80. The strip is loaded into the upper gripper and the substrate is clamped in the lower gripper 84, as shown in FIG. 18. The peel test is then carried out according to Standard Test Method ASTM D903, to produce a peel-force trace corresponding to the particular unitary film 40 which is being analysed.

The peel test is applied over a distance (e.g., strain) of 100 mm. The unitary film 40 is peeled from the substrate 82 at a peeling speed of 100 mm/min. Throughout the peel test, the peel-force which is exerted by the tensiometer on the film strips is continuously monitored by the controller. For example, the peel-force is measured at 10 μm intervals until the maximum peeling distance is reached (e.g., 100 mm). The peeling speed that is used for the peel testing is optimised so as to reliably obtain experimental results for such polymeric unitary films. The peeing speed is a balance between slower speeds which increase the duration of the peel test, and faster speeds which may cause damage to the unitary films.

The peeling force of the material is determined by taking an average from the data recorded in the peel-force trace. In particular, the average peel-force is calculated using only the data recorded after a minimum peeling distance has been achieved (e.g., 20 mm), to prevent distortions of the measurement caused by noise in the data which is present at the beginning of each test run.

Once the peel test is complete, the strip is removed from the gripper 84 and a different strip is loaded ready for testing. The peel test is repeated for each of the strips which are arranged and bonded to the substrate 82.

In a third method step 316, the peel-force traces for each of the strips is analysed to determine a peel strength for each of the corresponding sample films. In order for a polymeric film material to fulfil the second criterion, and thereby fall within the scope of the unitary film 40 according to the present disclosure, the material must exhibit a peel strength of at least 5 Newtons (N) per unit width (e.g., 10 mm) of the unitary film 40.

A summary of the results of the peel test analysis for each of the polymeric materials PM1-6 is presented in Table C, below. Each of the peel test measurements were performed on a strip of unitary film 40 having a width of 10 mm. Each of the materials PM1-6 has a peel strength which is within the required range to fulfil the second criterion (e.g., 5N per 10 mm width of the unitary film 40). FIGS. 20 and 21 show the peel-force traces of materials PM3 and PM6, respectively. For material PM3, the average peel force is 30N and for material PM6 the average peel force is 11N, as shown in Table C. Accordingly, material PM3 defines a (relatively) high peel strength material whereas PM6 defines a (relatively) low peel strength material.

TABLE C
Summary of peel strength results for polymeric
materials PM1-6 (FIGS. 21 and 22).

| Material | Peel strength (N) per 10 mm width |
|---|---|
| PM1 | 15 |
| PM2 | 30 |
| PM3 | 30 |
| PM4 | 13 |
| PM5 | 7 |
| PM6 | 11 |

According to a further exemplary condition of the second criterion, the peel strength must be at least 15N per 10 mm width of the unitary film 40. Accordingly, only materials PM1-3 satisfy this condition of the second criterion, but materials PM4-6 do not. Unitary films 40 which are formed of materials PM1-3 are particularly suited for use in an electrode assembly 12 of a solar cell, according to an exemplary aspect of the present disclosure. This is because the unitary films 40 provide enhanced adhesion with the conductive elements 18 and/or the surface of the solar cell, of the solar assembly.

According to an exemplary peel test method 310, the peel strength is required to be within a range of between 15N and 30N, per 10 mm width of the unitary film 40, in order to satisfy the second criterion. Once again, each of the materials PM1-3 fulfil this exemplary condition of the second criterion.

The unitary films 40 which are characterised according to the first and/or second criteria are advantageously configured with good adhesive properties (e.g., to ensure a mechanical connection between the film and the solar cell and/or conductive elements of the solar cell assembly). Each film is also advantageously configured such that it does not form an excessively, or uncontrollably, strong bonds with another element. In this way, the unitary films 40 help to ensure that manufacture of the electrode and/or solar cell assemblies is not disrupted.

It will be understood that the invention is not limited to the embodiments above described and various modifications and improvements can be made without departing from the concepts described herein. Except where mutually exclusive, any of the features may be employed separately or in combination with any other features and the disclosure extends to and includes all combinations and sub-combinations of one or more features described herein.

1. A unitary film for an electrode assembly of a solar cell, wherein the unitary film is arranged, when in use, on a surface of the solar cell and a plurality of electrically conductive elements of the electrode assembly are interposed between the unitary film and the surface of the solar cell;
wherein the unitary film is formed of a polymeric material and is characterised by satisfying at least one of a first criterion and a second criterion:
the first criterion requires that the polymeric material has at least two endothermic peaks in a temperature range between 40° C. and 200° C. measured by differential scanning calorimetry using the following method:
heating the unitary film, sequentially, in a first thermal cycle and a second thermal cycle according to Standard Test Method ASTM D3418 to produce a first heating trace and a second heating trace, respectively; and
identifying and determining a first endothermic peak and a second endothermic peak, in each of the first and second heating traces, in the temperature range between 40° C. and 200° C.;
the second criterion requires that the unitary film has a peel strength of at least 5N per 10 mm width of the unitary film, the peel strength determined by 180-degree peel test according to the following method:
thermally bonding the unitary film to a surface of a substrate;
peeling the unitary film from the surface according to Standard Test Method ASTM D903 to provide a peel-force trace; and
determining, from the peel-force trace, that the unitary film has a peel strength of at least 5N per 10 mm width of the unitary film.

2. A unitary film according to claim 1, wherein at least one of the first and second endothermic peaks in at least one of the first and second heating traces is between 80° C. and 160° C.

3. A unitary film according to claim 1, wherein the first endothermic peak in each of the first and second heating traces is between 40° C. and 130° C.

4. A unitary film according to claim 3, wherein the first endothermic peak in the second heating trace is between 80° C. and 130° C.

5. A unitary film according to claim 1, wherein the second endothermic peak in each of the first and second heating traces is between 100° C. and 160° C.

6. A unitary film according to claim 5, wherein the second endothermic peak in each of the first and second heating traces is between 100° C. and 145° C.

7. A unitary film according to claim 6, wherein the unitary film has a third endothermic peak in a temperature range between 130° C. and 200° C. in the first and second heating traces.

8. A unitary film according to claim 7, wherein the third endothermic peak in the first and second heating traces is between 130° C. and 160° C.

9. A unitary film according to claim 1, wherein the unitary film has an exothermic peak at a temperature in the range between 0° C. and 200° C. measured by the differential scanning calorimetry method which further comprises:
measuring the cooling of the polymer material during the first thermal cycle according to Standard Test Method ASTM D3418 to produce a cooling trace; and
identifying and determining the exothermic peak at a temperature in the range between 0° C. and 200° C.

10. A unitary film according to claim 9, wherein the exothermic peak is between 40° C. and 130° C.

11. A unitary film according to claim 1, wherein the peel-force trace of the unitary film is at least 15N.

12. A unitary film according to claim 1, wherein the peel-force trace of the unitary film is up to 30N.

13. A unitary film according to claim 1, wherein thermally bonding the unitary film to the substrate comprises heating the unitary film to at least 50° C.

14. A unitary film according to claim 1, wherein the unitary film satisfies both the first criterion and the second criterion.

15. A unitary film according to claim 1, wherein the polymeric material is formed from a polymer resin which comprises at least one of a polyolefin elastomer (POE), polyvinylbutyral (PVB) hydrocarbon ionomer, thermoplastic organo-silicon, silicon rubber, polyurethane, thermoplastic silicone elastomer (TPSE) and ethylene-vinyl acetate (EVA).

16. A unitary film according to claim 1, wherein the unitary film is configured with a haze parameter of less than 35%.

17. A unitary film according to claim 1, wherein the unitary film is configured to transmit at least 70% of incident light having a wavelength of between 280 nm and 1100 nm.

18. A unitary film according to claim 1, wherein the unitary film has a thickness of at least 25 μm.

19. An electrode assembly comprising a plurality of electrically conductive elements, and a unitary film according to claim 1, wherein the plurality of electrically conductive elements are arranged on a surface of the unitary film.

20. A solar cell assembly comprising a solar cell and an electrode assembly according to claim 19, wherein the plurality of electrically conductive elements are interposed between the unitary film and a surface of the solar cell.

21. A method of manufacturing an electrode assembly of a solar cell, wherein the electrode assembly comprises a plurality of electrically conductive elements and a unitary film according to claim 1; wherein the method comprises thermally bonding the unitary film to the plurality of electrically conductive elements.

22. A method of manufacturing a solar cell assembly, the solar cell assembly comprises a solar cell and an electrode assembly according to claim 19, wherein the method comprises:
interposing the plurality of electrically conductive elements between the unitary film and a surface of the solar cell, and
thermally bonding the unitary film to the plurality of electrically conductive elements and/or the surface of the solar cell.

23. A method according to claim 21, the method comprising thermally bonding the unitary film to the plurality of electrically conductive elements and the surface of the solar cell at substantially the same time.

24. A method according to claim 22, wherein thermally bonding the unitary film to the plurality of electrically conductive elements and/or the surface of the solar cell comprises heating the unitary film to a temperature which is substantially the same as the first endothermic peak of the second heating trace.

25. A method according to claim 22, wherein the method comprises, prior to thermally bonding the unitary film to the plurality of electrically conductive elements and/or the surface of the solar cell, heating the unitary film to a pre-bonding temperature which is substantially the same as the temperature of the first endothermic peak of the first heating trace.
